(19) United States
(12) Patent Application Publication
(10) Pub. No.: US 2012/0064649 A1
(43) Pub. Date: Mar. 15, 2012

(54) METHOD OF FORMING AN ALIGNMENT FILM FOR USE IN AN LCD PANEL

(75) Inventors: Chengming He, Shenzhen (CN); Hsiang-Yin Shih, Guangdong (CN)

(73) Assignee: SHENZHEN CHINA STAR OPTOELECTRONICS TECHNOLOGY CO., LTD., Guangming New District Shenzhen (CN)

(21) Appl. No.: 13/000,168

(22) PCT Filed: Nov. 10, 2010
(86) PCT No.: PCT/CN10/78618

§ 371 Date: Dec. 20, 2010

(30) Foreign Application Priority Data
Sep. 10, 2010 (CN) 201010283839.2

(51) Int. Cl. H01L 33/50; H01L 33/44

(52) U.S. Cl. 438/30; 438/780; 257/E33.06; 257/E33.067

(57) ABSTRACT

The present invention discloses a method of forming an alignment film for use in a liquid crystal display (LCD). The method includes: Provide a glass substrate and dispose an ITO film on the glass substrate. Next, set the thickness of the alignment film. Next, determine the spray volume of thin film material droplets based on the length and the width of the glass substrate. Next, spray a plurality of thin film material droplets in rows on the glass substrate through a plurality of nozzles of an inkjet head. The thin film material droplets are distributed in an approximate equilateral triangular pattern. The thin film material droplets in the shape of an approximate equilateral triangle can reduce instability when spreading on the glass substrate, achieving a target of optimized coatings. Finally, process an alignment material thin film which is formed after the thin film material droplets spread to form an alignment film.

### BACKGROUND OF THE INVENTION

1. Field of the Invention

The present invention relates to a method of fabricating a liquid crystal display (LCD) panel, and more particularly, to a method of fabricating an alignment film for use in an LCD panel.

2. Description of Prior Art

Please refer to FIG. 1, which is a partial cross-section view of an LCD panel 10. Two glass substrates 12a and 12b are equipped with a thin-film-transistor (TFT) 11 and a color filter (CF) 13, respectively. The TFT 11 and the CF 13 are overlaid with an indium tin oxide (ITO) film 14 which is covered with a polyimide (PI) thin film. The PI thin film undergoes a rubbing treatment, causing a plurality of parallel grooves to be incised on the PI thin film. The PI thin film with the plurality of parallel grooves is an alignment film 16. Liquid crystal molecules 18 are disposed along the plurality of grooves on the alignment film 16 so that the liquid crystal molecules 18 can be arranged in the same direction. The arranging direction of the liquid crystal molecules 18 varies depending on an electric field generated by a voltage difference between the ITO film 14 of the glass substrate 12a and the ITO film 14 of the glass substrate 12b. Meanwhile, the refractive index of the liquid crystal molecules varies, resulting in a change in the polarization direction of the incident light. The liquid crystal molecules will return to their original arranging direction once the electric field disappears. This is because a very strong anchoring strength exists at the interface of the liquid crystal molecules 18 and the alignment film 16.

Please refer to FIG. 2. Alignment film coating technology is as follows: High-density PI droplets 24 are sprayed at a high speed on the surfaces of the glass substrates 12a and 12b having a TFT or a CF through nozzles 26 of an inkjet head 22. A PI thin film is formed via diffusion of surface tension of the PI droplets 24. Next, the PI thin film undergoes contacted rubbing in a forward direction with a rotating rubbing roller, shaping a plurality of parallel grooves on the PI thin film. PI molecules are arranged in the plurality of parallel grooves in the forward direction. An advantage of alignment film coating technology is that the operative duration of the rubbing-induced orientation is quite short so that the technology can be operated under normal temperature. Owing to this advantage, alignment film coating technology is characteristic of rapid mass production.

Refer to FIG. 3 and FIG. 4 illustrating two kinds of distributions of the PI droplets 24 sprayed on a flat surface through the traditional inkjet head 22. Constrained by inkjet head fabrication technology, the arrangement and the pitch of the nozzle 26 of the inkjet head 22 are restricted. The nozzles 26 can simply be arranged alternatively in two rows, so only two simple patterns of droplets are shown on the flat surface. One is a matrix pattern and the other is a chess board pattern. The PI droplets 24 sprayed through the inkjet head 22 flow at the same speed on the flat surface if they are made of the same material. The differences in the fusion time of the PI droplets 24 causes the pitches of the nozzles 26 to be uneven and the surface to be unsmooth. Taking FIG. 3 for example, the PI droplets 24 sprayed through the nozzles 26 are arranged in a matrix while every two PI droplets 24 have a larger diagonal distance (√2a). The PI droplets 24 spread on the flat surface (dot region) cannot fill the midpoint of the diagonal distance, which causes an empty region 30. As shown in FIG. 4, the PI droplets 24 arranged in a chess board can avoid empty regions 30 that the PI droplets 24 arranged in a matrix has, but a problem that there are miss shots at corners happens instead, which causes the PI thin film near corners to be become thinner. One commonly used method nowadays for solving the problem is to supplement shots. But this method usually has a disadvantage of poor fusion.

Moreover, alignment process plays a very important role in flatness of the surface of the PI thin film, and the flatness of the surface of the PI thin film is highly related to patterns of droplets sprayed on the flat surface. A dot pitch is the most key factor to the influence on patterns of the droplets. In a cell structure, the distribution of the surface of the PI thin film is relevant to the profile of the surface of the glass substrate. The flatter a substrate is, the simpler a pattern shows. In other words, the less flat a substrate is, the rougher the surface of a PI thin film becomes. Owing to non-uniform brightness, mora is inclined to occur.

In addition, the industry is increasingly paying attention to environmental protection so resin is gradually replacing Cr. This is because traditional substrate material with plating Cr causes pollution easily. But the surface of resin is less smooth than that of Cr, and the PI droplets have viscosity. The PI droplets 24 cannot flow and spread well on the surface of a substrate made of resin. So, the industry uses new technology to solve the problem. The new technology is that the smaller PI droplets 24 are coated on the surface in order to make the surface as flat as possible when the PI droplets 24 do not flow. However, the technology is confined to fabrication technology of the inkjet head 22, so the size of the nozzles 26 of the inkjet head 22 used to spray the PI droplets 24 is restricted as well.

### SUMMARY OF THE INVENTION

It is therefore an object of the present invention to provide a method for spraying thin film material droplets on the glass substrate in the shape of an equilateral triangle. The thin film material droplets arranged in the shape of an equilateral triangle can reduce instability of diffusion of the thin film material droplets can be improved, which achieves a target of optimized coatings.

According to the present invention, a method for forming an alignment film for use in an LCD panel, the method comprising providing a glass substrate and an ITO film disposed on the glass substrate; determining a thickness of the alignment film; determine a spray volume of thin film material droplets based on the length and width of the glass substrate; spraying a plurality of rows of the thin film material droplets on the glass substrate through a plurality of nozzles of an inkjet head, the thin film material droplets being sprayed on every row in a first direction, the pitch between two thin film material droplets in every row being a first set value, the pitch between the thin film material droplets in adjacent two rows in a second direction being a second set value, wherein the second set value is equal to \sqrt{3} times the first set value; and processing a thin film formed after the plurality of thin film material droplets spread to form the alignment film.

In one aspect of the present invention, the first direction is perpendicular to the second direction.

In another aspect of the present invention, the glass substrate comprises a first side, the distance of a first thin film material droplet in one of the two adjacent rows being 1/\sqrt{3} times the first set value from the first side, and the distance of the first thin film material droplet in the other one of the two adjacent rows being \sqrt{3}/3+0.5 times the first set value from the first side.

In still another aspect of the present invention, a color filter or a thin film transistor is disposed between the glass substrate and the ITO film.

In still another aspect of the present invention, the thin film material droplets are made of polyimide (PI).

According to the present invention, a method for forming a liquid crystal display (LCD) panel is proposed. The method comprises providing a glass substrate; forming a color filter (CF) or a thin-film-transistor (TFT) on the glass substrate; forming an indium tin oxide (ITO) film on the CF or on the TFT; determining a thickness of an alignment film; determining a spray volume of thin film material droplets based on the length and width of the glass substrate; spraying a plurality of rows of the thin film material droplets on the glass substrate through a plurality of nozzles of an inkjet head, the thin film material droplets being sprayed on every row in a first direction, the pitch between two thin film material droplets in every row being a first set value, the pitch between the thin film material droplets in adjacent two rows in a second direction being a second set value, wherein the second set value is equal to \sqrt{3} times the first set value; processing a thin film formed after the plurality of thin film material droplets spread to form the alignment film; spraying liquid crystal molecules on the alignment film of the glass substrate having the TFT; and covering the glass substrate comprising the CF and the alignment film on the glass substrate having the TFT, the alignment film, and the liquid crystal molecules, and then dividing the glass substrate into a plurality of LCD panels.

Compared with the prior art, the present inventive method for forming an alignment film for use in an LCD panel is to control nozzles of an inkjet head to spray thin film material droplets on the glass substrate in the shape of an equilateral triangle. The thin film material droplets arranged in the shape of an equilateral triangle spread and form a PI thin film. The thickness of the PI thin film is more uniform, so the situation of instability of diffusion of the thin film material droplets can be improved, which achieves a target of optimized coatings.

These and other objectives of the present invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 is a partial cross-section view of an LCD panel.

FIG. 2 shows polyimide droplets sprayed on the surfaces of the glass substrate through nozzles of an inkjet head.

FIGS. 3 and 4 illustrates two kinds of distributions of the PI droplets sprayed on a flat surface through the traditional inkjet head.

FIG. 5 is a flowchart of forming an LCD panel according to the present invention.

FIG. 6 is a schematic diagram showing that thin film material droplets are sprayed on a glass substrate through an inkjet head according to the present invention.

FIG. 7 is a distribution diagram of the thin film material droplets sprayed on the glass substrate through the inkjet head according to the present invention.

FIG. 8 illustrates a plurality of parallel grooves on an alignment film with a rotating rubbing roller rolling in a forward direction.

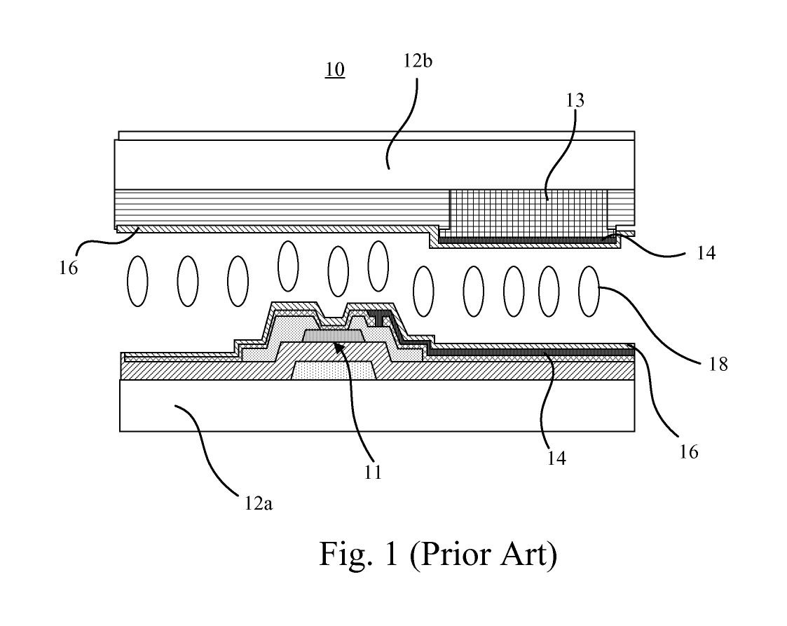

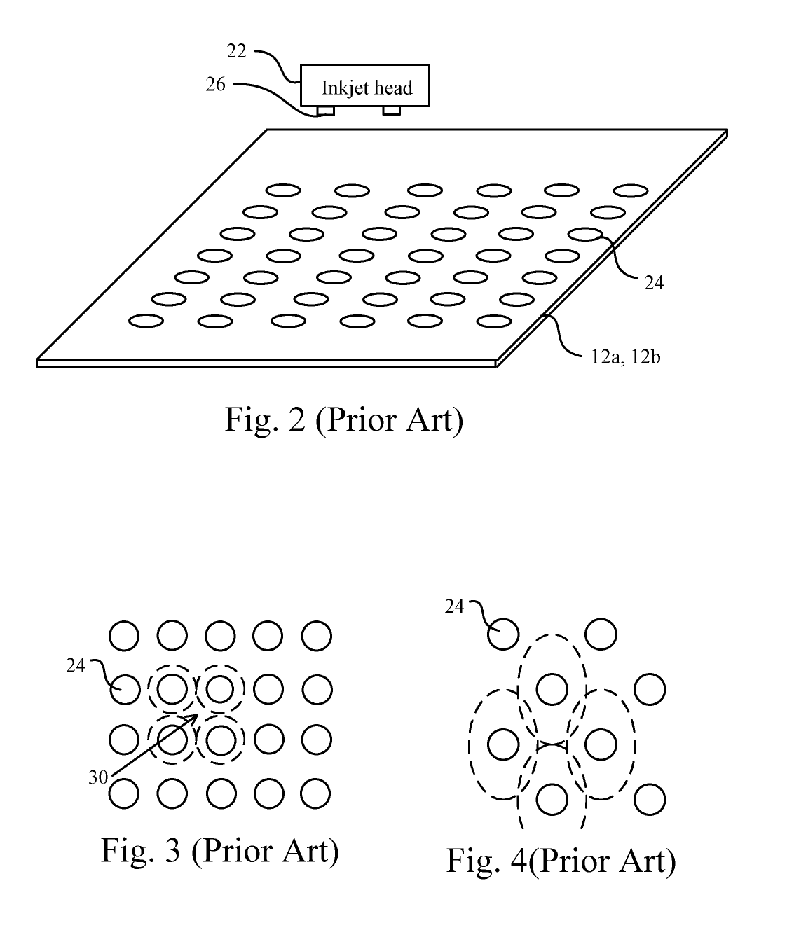

### DETAILED DESCRIPTION OF THE PREFERRED EMBODIMENTS

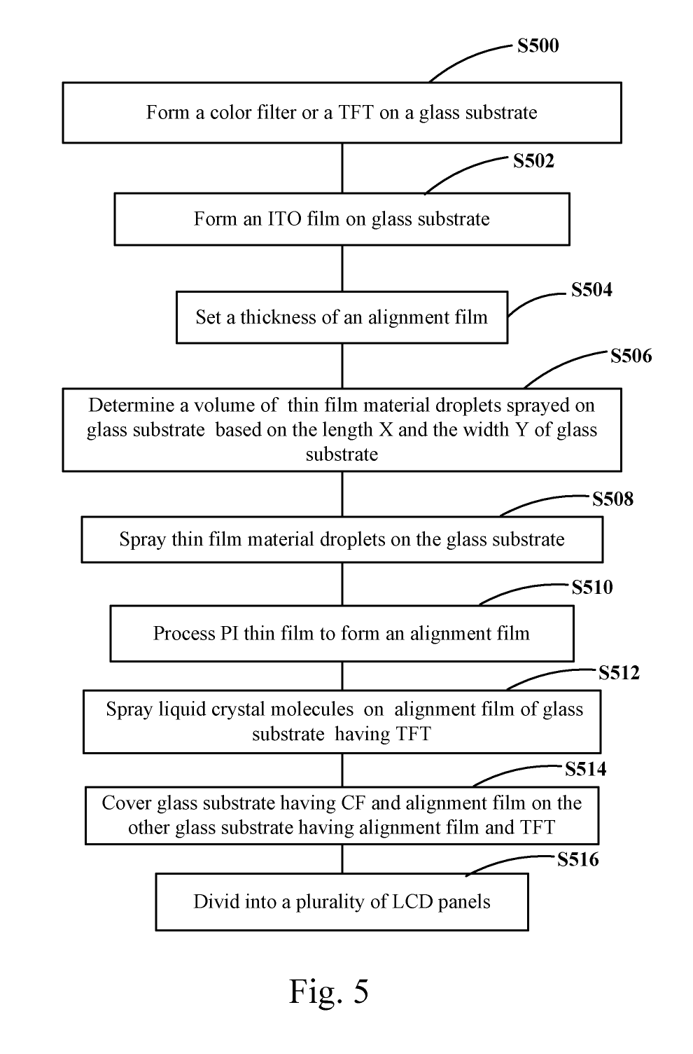

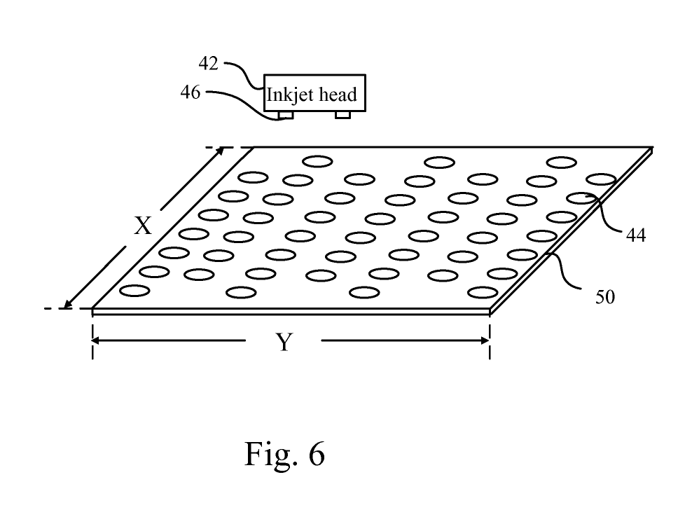

Refer to FIG. 5 and FIG. 6. FIG. 5 is a flowchart of forming an LCD panel according to the present invention, and FIG. 6 is a schematic diagram showing that thin film material droplets 44 are sprayed on a glass substrate 50 through an inkjet head 42 according to the present invention. The alignment material can be conventional PI, or other materials or combination materials which can form an alignment film. At First, a CF or a TFT is disposed on a cleaned glass substrate 50 (Step S500). Next, an ITO film (not shown) is disposed on the glass substrate 50 (Step S502). Next, the thickness of an alignment film is set (Step S504). Next, the volume of the thin film material droplets 44 sprayed on the glass substrate 50 is determined based on the length X and the width Y of the glass substrate 50 (Step S506). Finally, a plurality of rows of the thin film material droplets 44 are sprayed on the glass substrate 50 through a plurality of nozzles 46 of an inkjet head 42 (Step S508). To facilitate describing the present embodiment, the thin film material droplets 44 sprayed on the length of the glass substrate 50 in the X direction are set to be n+1 droplets and on the width of the glass substrate 50 in the Y direction through the inkjet head 42 are set to be m+1 droplets.

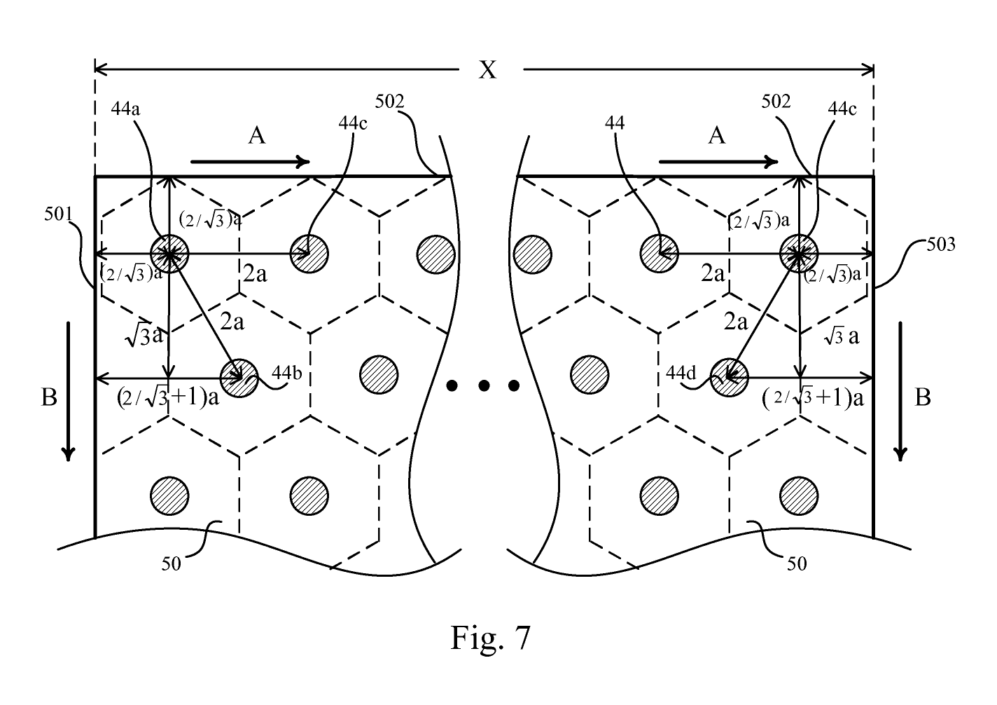

Refer to FIG. 7, which is a distribution diagram of the thin film material droplets 44 sprayed on the glass substrate 50 through the inkjet head 42 according to the present invention. Before the thin film material droplets 44 are spread on the glass substrate 50 through the inkjet head 42, the volume of the thin film material droplets 44 has to be determined based on the length X and the width Y of the glass substrate 50. Referring to FIG. 7, an algorithm related to how the inkjet head 42 determines the spray volume of the thin film material droplets 44 is elaborated in the following. Firstly, the first thin film material droplet 44a sprayed on the first row through the inkjet head 42 has a distance of (2/\sqrt{3})a from both sides 501 and 502 of the glass substrate 50. Secondly, the thin film material droplets 44 in each row are sprayed in a first direction A which is parallel to the extended direction of the width X. The pitch between every two thin film material droplets 44 is a first set value. The first set value is 2a. The last thin film material droplet 44c sprayed on the first row has a distance of (2/\sqrt{3})a from both sides 502 and 503 of the glass substrate 50. So the spray volume n+1 of the thin film material droplets 44 for the first row is determined based on the first formula as shown below:

(2/\sqrt{3}×2+n×2)·a=X, Equation (1)

where X represents the width of the glass substrate 50, and 2a represents the first set value.

The first thin film material droplet 44b sprayed on the next row has a distance of (2/\sqrt{3}+1)a and of (5\sqrt{3}/3)a from both sides 501 and 502 of the glass substrate 50, respectively. That is, the distance between the first thin film material droplet 44a and the first thin film material droplet 44b in any adjacent two rows in the first direction A and in the second direction B is a and \sqrt{3}a (a second set value), respectively. The second direction B is parallel to the extended direction of the length Y; (i.e., the second direction B is perpendicular to the first direction A). The pitch of the two adjacent thin film material droplets 44 in each row in the first direction A is the first set value (2a). The last thin film material droplet 44d sprayed on the second row has a distance of (2/\sqrt{3}+1)a and of (5\sqrt{3}/3)a from both sides 503 and 502 of the glass substrate 50, respectively. So the spray volume m+1 of the thin film material droplets 44 in the second direction B is determined based on the second formula as shown below:

[2·(2/\sqrt{3})+2·\sqrt{3}·m]·a=Y, Equation (2)

where Y represents the length of the glass substrate 50.

Afterwards, the rule for the thin film material droplets 44 to be sprayed on the third row is the same as that on the first row, and the rule for the thin film material droplets 44 to be sprayed on the fourth row is the same as that on the second row. The two rules appear alternatively until the spray volume of the thin film material droplets 44 is enough to form a thin film which covers the glass substrate 50 entirely.

Based on the above-mentioned algorithm, the three adjacent thin film material droplets 44 (e.g., the adjacent thin film material droplets 44a-44c) in two adjacent rows on the glass substrate 50 are arranged in the shape of an approximate equilateral triangle. That is, the pitch between every two thin film material droplets 44a-44c is the first set value (2a). Generally speaking, the thin film material droplets 44 are made of PI or similar macromolecules and have viscosity. The diffusion shape of the dropped thin film material droplets 44 is mostly circular. The thin film material droplets 44 make an arrangement of an approximate equilateral triangle among one another, so they form an approximate regular hexagon (or called “honeycomb”) after spreading out and cover the entire surface of the glass substrate 50 uniformly. As for a naturally planar arrangement, a regular hexagon is the most similar to a circle, so the thin film material droplets 44 can form a more uniformed PI thin film after spreading.

According to the above-mentioned calculation rules, operating personnel can set the volume of the thin film material droplets 44, a spay pitch, and a spread radius in advance based on the thickness of the PI thin film that is required and the length and the width of the glass substrate 50. In other words, the aforementioned parameters and calculation rules can be edited as a standard operation procedure (SOP) in the photoresist/LC filling process to suit the liquid forming process. So operating personnel can set the parameters to simplify the process based on variations of size of the glass substrate 50. Meanwhile, a plurality of thin film material droplets 44 in the shape of an approximate equilateral triangular pattern make a thin film spread more evenly, which accordingly improves the situation of unevenness of the PI thin film because of the profile of the surface of the glass substrate 50 or the material differences in the glass substrate 50.

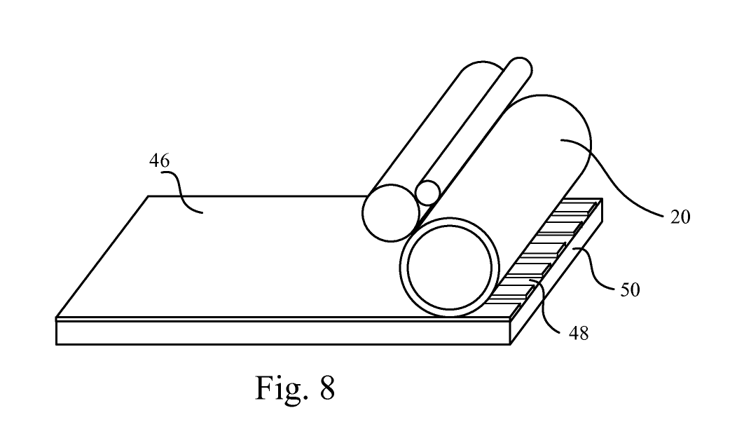

Refer to FIG. 5 and FIG. 8. FIG. 8 illustrates a plurality of parallel grooves 48 on an alignment film 46 with a rotating rubbing roller 20 rolling in a forward direction. A PI thin film is formed via diffusion of surface tension of the thin film material droplets 44. Afterwards, the PI thin film can be processed to form the alignment film 46 by means of processing methods (S510). Commonly used process methods include photo alignment and rubbing. The photo alignment method is that polarized ultraviolet light (UV) is irradiated onto the PI thin film in a specific direction to induce optical anisotropy. The rubbing method is that the rotating rubbing roller 20 contacts with the PI thin film in a forward direction to incise a plurality of parallel grooves 48 so that PI molecules can be arranged in a forward direction, as shown in FIG. 8. Afterwards, liquid crystal molecules are sprayed on the alignment film 46 of the glass substrate 50 having the TFT (S512). Finally, the glass substrate 50 having the CF (not shown) and the alignment film 46 covers on the glass substrate 50 having the TFT (not shown), the alignment film 46, and liquid crystal molecules (S514), and then the glass substrate 50 is divided into a plurality of LCD panels (S516).

Although the present invention has been explained by the embodiments shown in the drawings described above, it should be understood to the ordinary skilled person in the art that the invention is not limited to the embodiments, but rather various changes or modifications thereof are possible without departing from the spirit of the invention. Accordingly, the scope of the invention shall be determined only by the appended claims and their equivalents.

What is claimed is:

1. A method for forming a liquid crystal display (LCD) panel, the method comprising providing a glass substrate, the glass substrate comprising a first side and a second side perpendicular to the first side, forming a color filter (CF) or a thin-film-transistor (TFT) on the glass substrate, and forming an indium tin oxide (ITO) film on the CF or on the TFT, characterized in that the method further comprise:
determining a thickness of an alignment film;
determining a spray volume of thin film material droplets based on the length and width of the glass substrate;
spraying a plurality of rows of the thin film material droplets on the glass substrate through a plurality of nozzles of an inkjet head, the thin film material droplets being sprayed on every row in a first direction, the pitch between two thin film material droplets in every row being a first set value, the pitch between the thin film material droplets in adjacent two rows in a second direction being a second set value, wherein the second set value is equal to \sqrt{3} times the first set value, wherein the distance of a first thin film material droplet in one of the two adjacent rows is 1/\sqrt{3} times the first set value from the first side, and the distance of the first thin film material droplet in the other one of the two adjacent rows is \sqrt{3}/3+0.5 times the first set value from the first side, wherein the distance of a first thin film material droplet in one of the two adjacent columns is 1/\sqrt{3} times the first set value from the second side, and the distance of the first thin film material droplet in the other one of the two adjacent columns is 5\sqrt{3}/6 times the first set value from the second side;
processing a thin film formed after the plurality of thin film material droplets spread to form the alignment film;
spraying liquid crystal molecules on the alignment film of the glass substrate having the TFT; and
covering the glass substrate comprising the CF and the alignment film on the glass substrate having the TFT, the alignment film, and the liquid crystal molecules, and then dividing the glass substrate into a plurality of LCD panels.

2. The method of claim 1 characterized in that the first direction is perpendicular to the second direction.

3. The method of claim 1 characterized in that the thin film material droplets are made of polyimide (PI).

4. A method for forming an alignment film for use in an LCD panel with, the method comprising providing a glass substrate and an ITO film disposed on the glass substrate, characterized in that the method further comprise:
determining a thickness of the alignment film;
determine a spray volume of thin film material droplets based on the length and width of the glass substrate;
spraying a plurality of rows of the thin film material droplets on the glass substrate through a plurality of nozzles of an inkjet head, the thin film material droplets being sprayed on every row in a first direction, the pitch between two thin film material droplets in every row being a first set value, the pitch between the thin film material droplets in adjacent two rows in a second direction being a second set value, wherein the second set value is equal to \sqrt{3} times the first set value; and
processing a thin film formed after the plurality of thin film material droplets spread to form the alignment film.

5. The method of claim 4 characterized in that the first direction is perpendicular to the second direction.

6. The method of claim 4 characterized in that the glass substrate comprises a first side, the distance of a first thin film material droplet in one of the two adjacent rows being 1/\sqrt{3} times the first set value from the first side, and the distance of the first thin film material droplet in the other one of the two adjacent rows being \sqrt{3}/3+0.5 times the first set value from the first side.

7. The method of claim 5 characterized in that the glass substrate comprises a second side, the first side being perpendicular to the second side, the distance of a first thin film material droplet in one of the two adjacent columns being 1/\sqrt{3} times the first set value from the second side, and the distance of the first thin film material droplet in the other one of the two adjacent columns being 5\sqrt{3}/6 times the first set value from the second side.

8. The method of claim 4 characterized in that a CF or a TFT is disposed between the glass substrate and the ITO film.

9. The method of claim 4 characterized in that the thin film material droplets are made of PI.

10. A method for forming a uniform thin film, the method comprising providing a substrate, characterized in that the method further comprise:
determine a spray volume of droplets based on the length and width of the substrate; and
spraying a plurality of rows of the droplets on the glass substrate through a plurality of nozzles of an inkjet head, the droplets being sprayed on every row in a first direction, the pitch between two droplets in every row being a first set value, the pitch between the thin film material droplets in adjacent two rows in a second direction being a second set value, wherein the second set value is equal to \sqrt{3} times the first set value.

11. The method of claim 10 characterized in that the first direction is perpendicular to the second direction.

12. The method of claim 10 characterized in that the glass substrate comprises a first side, the distance of a first thin film material droplet in one of the two adjacent rows being 1/\sqrt{3} times the first set value from the first side, and the distance of the first thin film material droplet in the other one of the two adjacent rows being \sqrt{3}/3+0.5 times the first set value from the first side.

13. The method of claim 11 characterized in that the glass substrate comprises a second side, the first side being perpendicular to the second side, the distance of a first thin film material droplet in one of the two adjacent columns being 1/\sqrt{3} times the first set value from the second side, and the distance of the first thin film material droplet in the other one of the two adjacent columns being 5\sqrt{3}/6 times the first set value from the second side.

14. The method of claim 10 characterized in that a material of the droplets is PI.

15. The method of claim 10 characterized in that the substrate is made of glass.
